(19) United States
(12) Patent Application Publication
(10) Pub. No.: US 2009/0130603 A1
(43) Pub. Date: May 21, 2009

(54) METHOD FOR MANUFACTURING SEMICONDUCTOR DEVICE

(75) Inventor: Tomohiko YAMAMOTO, Kawasaki (JP)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: FUJITSU MICROELECTRONICS LIMITED, Tokyo (JP)

(21) Appl. No.: 12/268,735

(22) Filed: Nov. 11, 2008

(30) Foreign Application Priority Data
Nov. 21, 2007 (JP) 2007-301667

(51) Int. Cl. G03F 7/00

(52) U.S. Cl. 430/319

(57) ABSTRACT

A method for manufacturing a semiconductor device includes the steps of: forming a resist film above a semiconductor wafer having a layer to be processed, the resist film not being formed on a circumferential portion of the semiconductor wafer; exposing the resist film; after exposing the resist film, forming a resist pattern by developing the resist film; after forming the resist pattern by developing the resist film, cleaning the semiconductor wafer by supplying a thinner to the circumferential portion of the semiconductor wafer; and after cleaning the semiconductor wafer, processing the layer to be processed of the semiconductor wafer using the resist pattern.

This application is based upon and claims the benefit of priority of the prior Japanese Patent Application No. 2007-301667, filed on Nov. 21, 2007, the entire contents of which are incorporated herein by reference.

### BACKGROUND

1. Field

The present invention relates to a method for manufacturing a semiconductor device including a step of performing processing with a resist film as a mask.

2. Description of the Related Art

In the manufacture of semiconductor devices, the resist plays an important role. In etching processes, for instance, a resist film is formed on the film to be processed, and openings which expose regions for etching on the film to be processed are then formed in the resist film. In ion implantation, regions in which ion implantation is not performed are covered by the resist film. The number of resist films used as masks has a significant effect on cost and yield in the manufacture of semiconductor devices.

The resist films are generally applied to the surface of the semiconductor wafer as a solution using a spinner. Resist solution supplied to a central portion of the semiconductor wafer is spread towards the periphery in a radial direction by centrifugal force, and thereby reaches the edge portion of the wafer. When multiple chips are prepared on the semiconductor wafer, the circumferential portion of the wafer where full-sized chips cannot be disposed is not generally used to form semiconductor devices. However, the resist film applied using the spinner is formed on the circumferential portion as well as the non-circumferential portion. When the resist film is present on the circumferential portion of the wafer, the resist film contacts members such as the wafer cassette and the wafer holder. These contacts can generate particles and debris. To avoid this, processing to remove the resist film from the circumferential portion of the wafer is performed.

Japanese Patent Laid-Open No. H6-326014 proposes a spin coating apparatus having a coating liquid jetting means for jetting coating liquid such as resist solution towards a central portion of a top side of a semiconductor wafer and a solvent jetting means for jetting a solvent for dissolving the coating liquid onto the circumferential portion of the semiconductor wafer.

Japanese Patent Laid-Open No. H7-183208 proposes supplying, in a developing step, a developer to the rear surface of the semiconductor wafer to dissolve and remove the resist film remaining on the semiconductor on the circumferential portion and edge portion of the wafer.

Japanese Patent Laid-Open No. H10-199791 proposes initially performing first development processing which is conventional development processing and then performing second development processing for removing the resist pattern solute that remains adhered to the circumferential portion of the semiconductor wafer.

Japanese Patent Laid-Open No. H10-104847 and Japanese Patent Laid-Open No. 11-109654 propose use of a thinner of a specific composition for removing unnecessary resist that has adhered to the circumferential portion and rear surface of the semiconductor wafer after the soft bake and before the exposure and development of the resist film.

### SUMMARY

According to an aspect of an embodiment, a method for manufacturing a semiconductor device includes the steps of: forming a resist film above a semiconductor wafer having a layer to be processed, the resist film not being formed on a circumferential portion of the semiconductor wafer; exposing the resist film; after exposing the resist film, forming a resist pattern by developing the resist film; after forming the resist pattern by developing the resist film, cleaning the semiconductor wafer by supplying a thinner to the circumferential portion of the semiconductor wafer; and after cleaning the semiconductor wafer, processing the layer to be processed of the semiconductor wafer using the resist pattern.

### BRIEF DESCRIPTION OF THE DRAWINGS

FIG. 1 is a flowchart showing main steps in a method of manufacturing a semiconductor device according to an embodiment;

FIG. 2A is an optical micrograph of a circumferential portion of a semiconductor wafer taken after developing and before cleaning with a thinner;

FIG. 2B is an optical micrograph of the circumferential portion of the semiconductor wafer taken after developing and after cleaning with the thinner;

FIG. 3A is a side view of the semiconductor wafer showing a thinner cleaning process;

FIG. 3B is a side view of the semiconductor wafer showing a thinner cleaning process;

FIG. 3C is a side view of the semiconductor wafer showing a thinner cleaning process;

FIG. 4A is a cross-sectional view of the semiconductor wafer in an intermediate state of a semiconductor device manufacturing method;

FIG. 4B is a cross-sectional view of the semiconductor wafer in an intermediate state of the semiconductor device manufacturing method;

FIG. 4C is a cross-sectional view of the semiconductor wafer in an intermediate state of the semiconductor device manufacturing method; and

FIG. 5 is a cross-sectional view of the semiconductor wafer schematically showing a structure of the semiconductor device.

### DESCRIPTION OF EMBODIMENT

The following describes an embodiment of a method of manufacturing a semiconductor device.

Conventionally, processing using a solvent is performed on front and rear surfaces of the wafer after applying an anti-reflection film, a resist film and a top-coat film. As a result, the circumferential portion on the semiconductor wafer on which the films have been formed is maintained in a clean state. However, it has been discovered that foreign matter often adheres to the circumferential portion of the wafer after the development processing.

The inventor considered what caused the foreign matter which was found on the wafer after the development processing.

In positive photoresist, for instance, a protective group is attached to the resin that forms the main chain. In locations irradiated with light in the exposure, the protective group is separated from the main chain by heat treatment which follows the exposure. When the film is developed, the main chain then begins to dissolve in the developer. In locations not irradiated with light, however, the protective group remains and so the main chain is not dissolved in the developer, and the photoresist is left behind to form a pattern.

The photoresist that is fully irradiated by the light dissolves completely in the developer. The photoresist that is not completely irradiated does not completely dissolve and is left over on the substrate. Thus, when the photoresist is only partially irradiated, the developer may be expected to only partially dissolve the photoresist so that a certain amount of residue is left on the substrate. In other words, the partially irradiated photoresist does not fully dissolve in the developer and a residue remains on the substrate.

Since alcohols cannot dissolve molecules having a high molecular weight, such residues cannot be removed with an alcohol such as isopropyl alcohol. Even if the concentration of the developer is raised, it will not to be possible to use the developer to remove the photoresist for which the exposure was insufficient to allow dissolution in the developer.

To solve this problem, the inventor conceived of cleaning (for example rinsing) the circumferential portion of the wafer after development using a thinner in which the photoresist is highly soluble irrespective of the level of exposure. Such a thinner is capable of removing the photoresist that remains after development. By cleaning with the thinner, it will be possible to completely remove the foreign matter deriving from the photoresist.

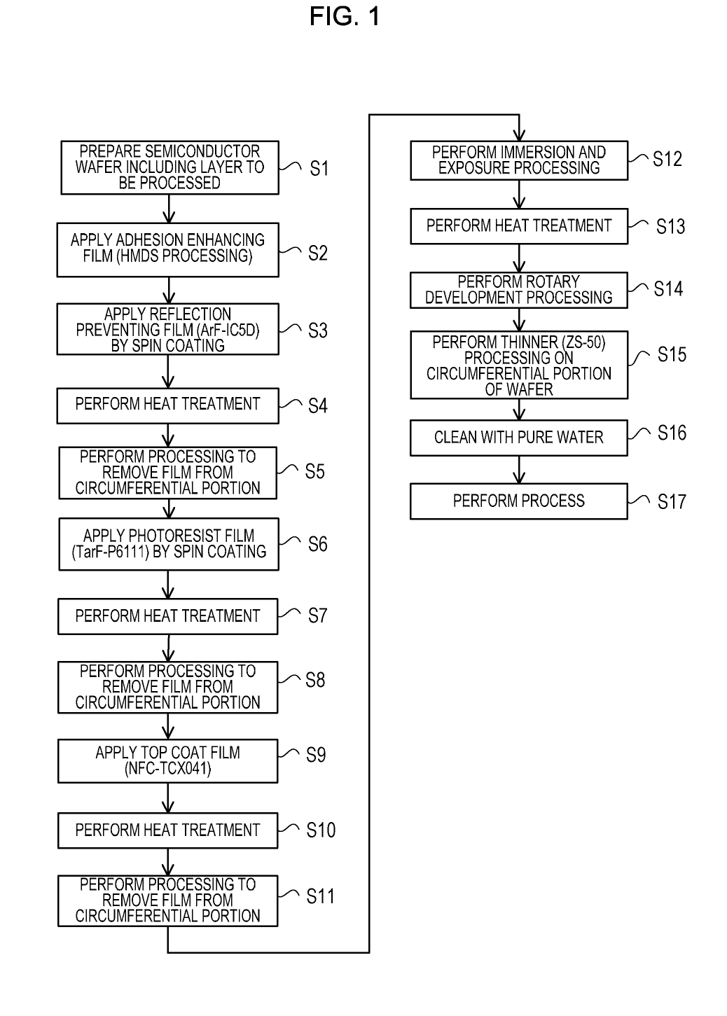

FIG. 1 is a flowchart showing main processes in a semiconductor device manufacturing method according to an embodiment.

In step S1, the silicon wafer having the film to be processed formed thereon is prepared. The film to be processed is, for example, a polycrystalline or amorphous silicon film used to form gate electrodes.

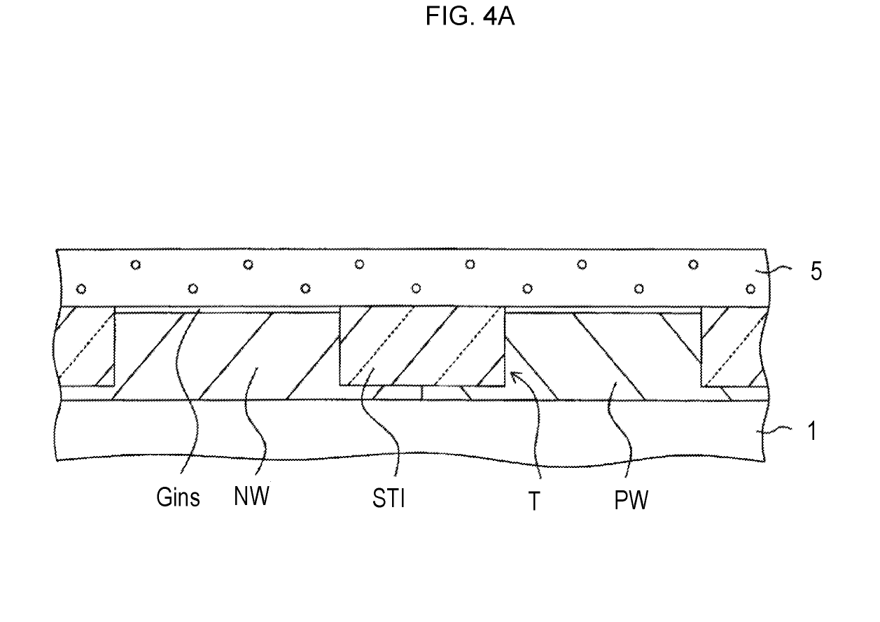

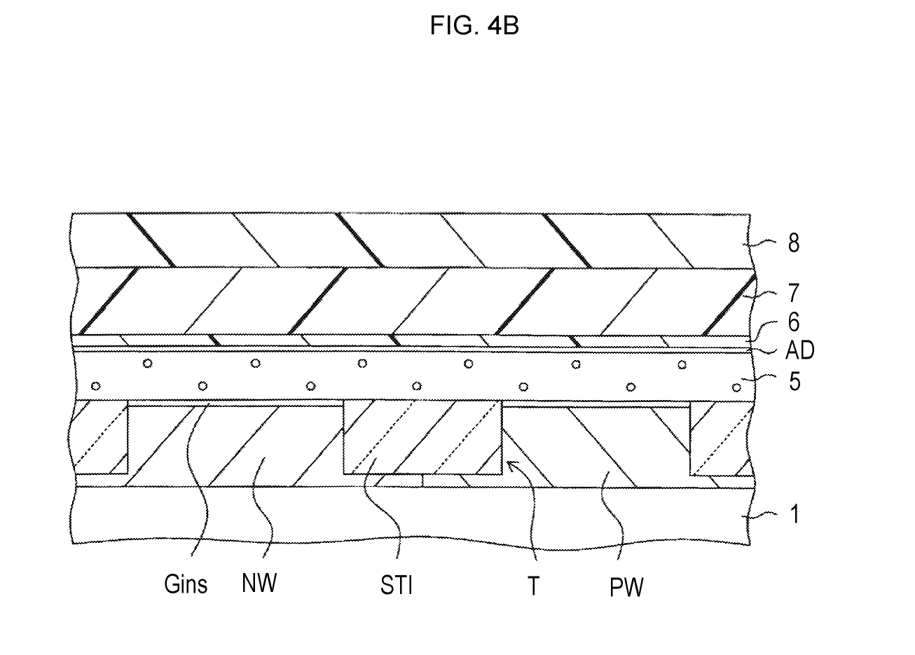

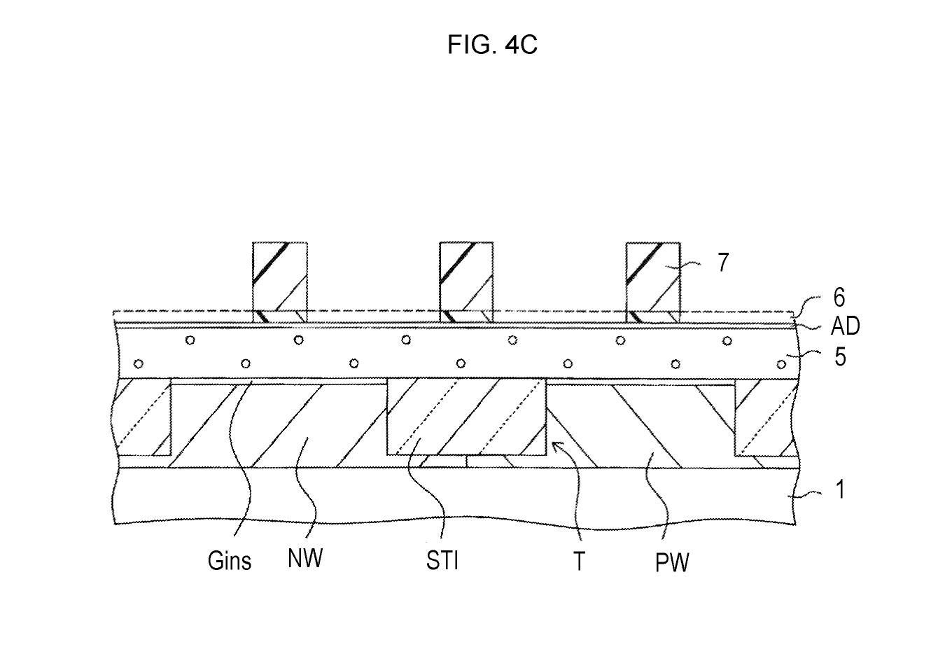

FIG. 4A shows an example structure of a silicon wafer. The silicon wafer 1 has trenches T formed therein. The trenches T are filled with an insulating film such as silicon oxide. Unnecessary portions of the insulating film are then removed to form device isolation regions STI called shallow trench isolation. Next, an n-type well NW and a p-type well PW are formed by selective ion implantation. A gate insulating film Gins is formed by oxidation or introduction of nitrogen to the surfaces of active regions defined by the device isolation regions STI. The gate insulating film Gins is covered using a polycrystalline silicon film 5 which is formed using CVD (Chemical Vapor Deposition) on the top side of the semiconductor wafer.

In an example of preparing a test sample, a substrate, having a gate oxide film, a polycrystalline silicon film, and an oxide film formed on a silicon wafer in the stated order, is used.

In step S2, an adhesion enhancing film is applied to the top side of the wafer to enhance adhesion between the wafer having the film to be processed and the applied film. In the example, the adhesion enhancing film is applied after performing HMDS (hexamethyldisilazane) processing on the semiconductor wafer. The HMDS processing is performed by heat-treating the wafer in an atmosphere of HMDS at 90° C. for 60 seconds.

In step S3, a reflection preventing film is applied to the adhesion enhancing film by spin coating. In the example, ArF-1C5D made by AZ Electronic Materials (Japan) Co., Ltd. is used as the reflection preventing film. The application conditions are as follows. A 1 cc quantity of reflection preventing film material liquid is discharged in drops onto the wafer, and the wafer is then rotated at 3000 rpm. As a result, the reflection preventing film covers the wafer with a film having a thickness of 80 nm.

Note that the reflection preventing film may alternatively be formed using any of the followings: an acryl resin including aromatic side chain such as an anthracene; an aromatic resin including a benzene, a naphthalene, an anthracene or the like; a vinyl styrene resin; a novolak resin; a bisphenol-containing resin; an organic material such as an acryl-aromatic material copolymer; or an inorganic material such as a silicon material (a polysilane or polysiloxane).

In step S4, the reflection preventing film is heat-treated. In the example, the reflection preventing film is heat-treated at 190° C. for 60 seconds.

In step S5, the processing using a solvent is performed to clean the reflection preventing film at the circumferential portion of the wafer. In the example, a thinner called ZS-50 is used as the solvent. 20 cc of the thinner is jetted towards the wafer for one minute while rotating the wafer at a rotational speed of 3000 rpm. When jetting the thinner, the thinner nozzle is inclined at an angle of 45° with respect to the top surface of the semiconductor wafer. During the jetting, the nozzle is scanned towards the wafer edge from a position 2 mm from the wafer edge.

In step S6, the photoresist, which is a photosensitive resin, is applied onto the reflection preventing film by spin coating. In the example, TarF-P6111 manufactured by Tokyo Ohka Kogyo Co., Ltd. is used as the photoresist. The application conditions are as follows. A 1 cc quantity of resist material is discharged in drops onto the wafer, and the wafer is rotated at 3000 rpm. As a result, a resist film with a thickness of 200 nm is formed on the wafer.

Possible alternatives for the photosensitive resin include an acryl resin having an adamantyl group in a side chain, a COMA (cycloolefin maleic anhydride) resin, a hybrid resin (an alicyclic acryl-COMA copolymer), and a cycloolefin resin.

In step S7, the photoresist is heat-treated. In the example, the photoresist film is heat-treated at 110° C. for 60 seconds.

In step S8, processing using a solvent is performed to clean the photoresist film at the circumferential portion of the wafer. In the example, a thinner called ZS-50 is used as the solvent. 20 cc of the thinner is jetted towards the wafer for one minute while rotating the wafer at a rotation speed of 3000 rpm. When jetting the thinner, the thinner nozzle is inclined at an angle of 45° with respect to the top surface of the semiconductor wafer. During the jetting, the nozzle is scanned towards the wafer edge from a position 1.5 mm from the wafer edge.

In step S9, a top coat film, which is protective film, is applied to the photoresist film. In the example, NFC-TCXO41 manufactured by JSR Co., Ltd. is used as the top coat. The application conditions are as follows. A 5 cc quantity of top coating material is discharged in drops onto the wafer, and the wafer is rotated at 3000 rpm. As a result, a top coat film with a thickness of 50 nm is formed on the wafer.

The top coat film is formed using a material which does not easily mix with the underlying ArF resist film, and which is transparent to light targeted at the ArF film and sufficiently hydrophobic to allow use of an immersion method. For instance, the top coat film may be a fluorine-containing or a hydrocarbon resin. Examples of fluorine-containing resins include acryl resins having a fluorine-containing group in a side chain, poly-cycloolefin resins, such as poly-norbornene resins, that have a fluorine-containing functional group in a side chain, and resins that have been fluorinated. Suitable hydrocarbon resins include poly-cycloolefin and poly-olefin resins.

In step S10, the top coat film is heat-treated. In the example, the top coat film is heat-treated at 90° C. for 60 seconds.

In step S11, the processing with a solvent is performed to clean the top coat film at the circumferential portion of the wafer. In the example, the thinner called ZS-50 is used as the solvent. 150 cc of the thinner is jetted towards the wafer for one minute while rotating the wafer at a rotation speed of 3000 rpm. When jetting the thinner, the thinner nozzle is inclined at an angle of 45° with respect to the top surface of the semiconductor wafer.

FIG. 4B shows the state of the wafer after a three-layer resist structure has been formed thereon. An adhesion enhancing film AD, has been formed on the polycrystalline silicon film 5. A reflection preventing film 6, a positive resist film 7, and a top coat film 8 are formed on the adhesion enhancing film AD in the stated order.

In step S12, the semiconductor wafer having the photoresist film formed thereon is then exposed using an ArF immersion lithography apparatus. An exposure of 20 mJ is used.

In step S13, heat treatment for the photoresist film is then performed on the exposed semiconductor wafer. In the example, the photoresist film is heat-treated at 130° C. for 60 seconds.

In step S14, development is performed using a rotary developing apparatus. In the example, tetramethyl ammonium hydroxide (TMAH 2.38%) is used as the developer. The developer is discharged in drops onto the wafer with the wafer held in an immovable state. The wafer is then held in the immovable state for 30 seconds. Thereafter, the wafer is cleaned with pure water while rotating the wafer. 1000 cc of pure water is supplied for one minute. Thereafter, the supply of pure water is stopped and the water is shaken off by rotating the wafer at 4000 rpm.

In the development processing, the top coat film is dissolved and washed away and the unnecessary portion of the photoresist film, which has been exposed, is dissolved. The dissolved film-derived materials are removed together with the developer. When the reflection preventing film is an organic film of a similar type to the photoresist, the reflection preventing film exposed in the openings of the photoresist film is also removed.

FIG. 4C schematically shows the state of the semiconductor wafer after development. The top coat film 8 is dissolved and removed, and the resist film 7 and the reflection preventing film 6 undergo patterning.

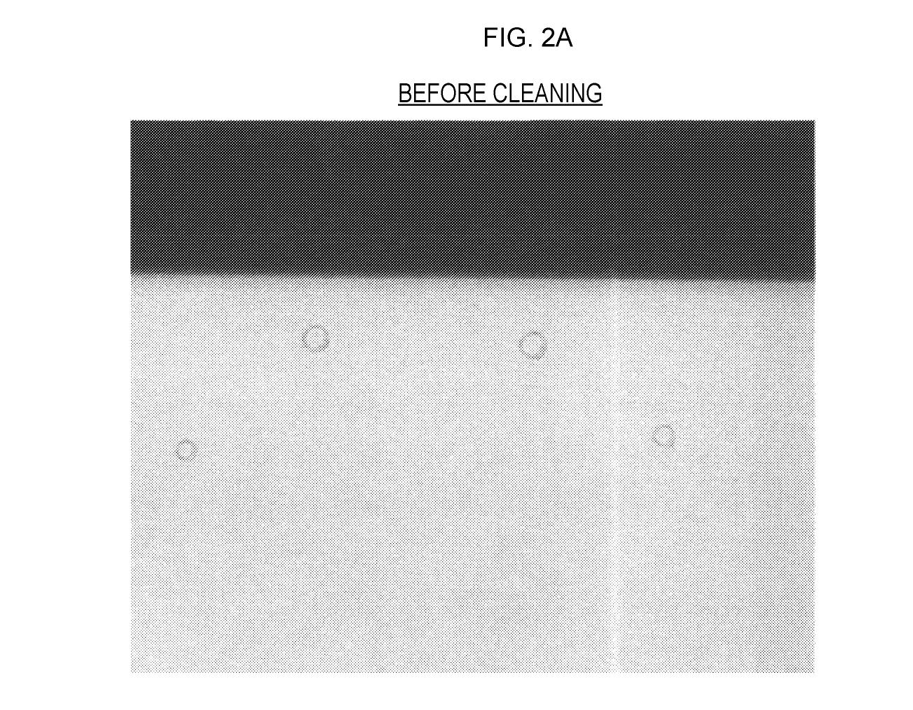

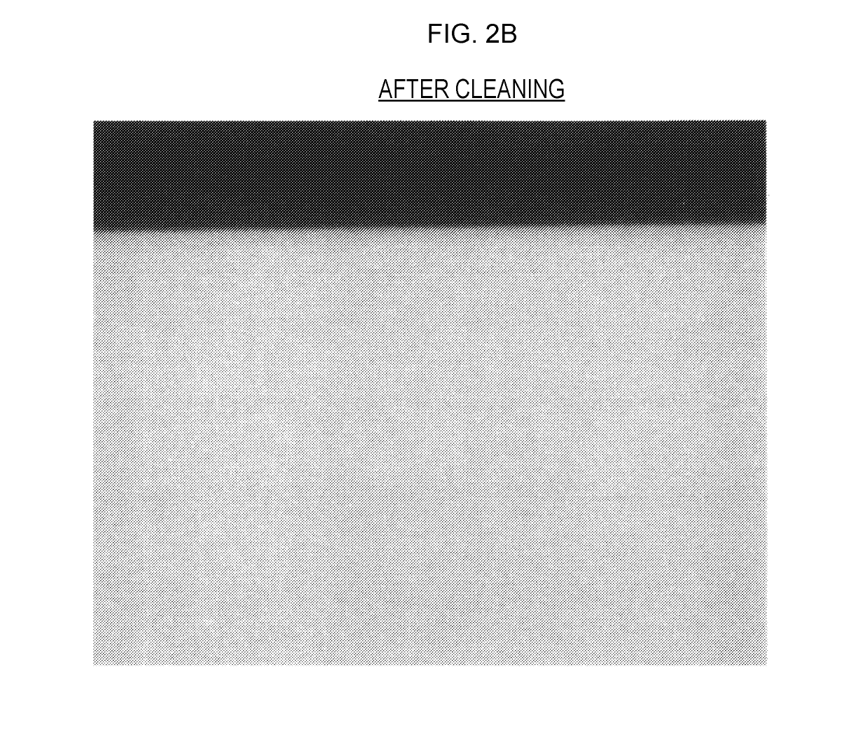

FIG. 2A is an optical micrograph of a circumferential portion of a semiconductor wafer after development processing. Particles, which appear as circles in the micrograph, have adhered to the circumferential portion of the semiconductor wafer. Such particles lower the accuracy in the following processes, thereby reducing the yield.

In step S15, processing using a thinner is performed on the circumferential portion of the wafer for cleaning the portion both after the development processing and before the etching process. In the example ZS-50 made by Zeon Japan Co., Ltd is used as the thinner. The conditions for the processing using the thinner are as follows. The thinner called ZS-50 is used as the solvent. 20 cc of the thinner is jetted towards the wafer for one minute from above while rotating the wafer at a rotation speed of 3000 rpm. When jetting the thinner, the thinner nozzle is inclined at an angle of 45° with respect to the top surface of the semiconductor wafer. During the jetting, the nozzle is scanned towards the wafer edge from a position 1.5 mm from the wafer edge. At the same time, 150 cc of thinner per minute is jetted at the wafer from below at an angle of 45° to the wafer surface.

The thinner can be a single solvent or a mixture of solvents which effectively dissolve the resist film, the reflection preventing film, and the top coat film. Such solvent includes esters, ethers, lactones, and ketones. For instance, one or more of butyl oxide, propylene glycol monomethyl ether acetate, propylene glycol monomethyl ether γ-butyrolactane, 2-hexanone, 3-methoxybutyl acetate, ethyl lactate, methyl amyl ketone, ethyl 2-hydroxypropanoate, anisole, and the like may be used.

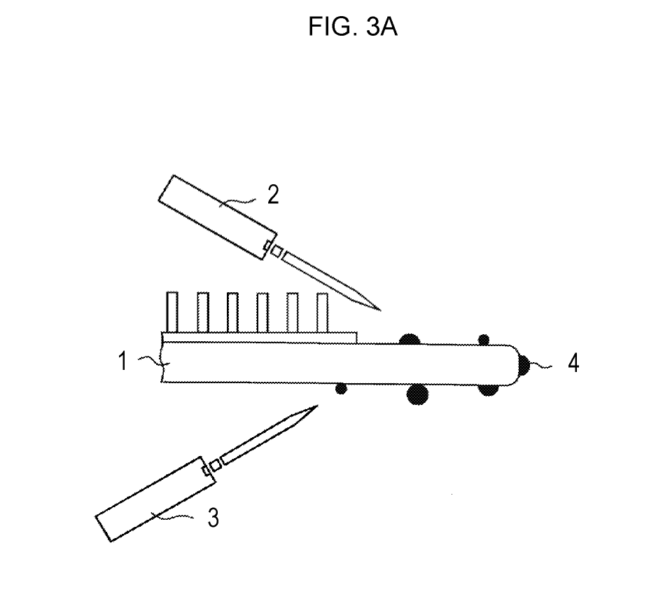

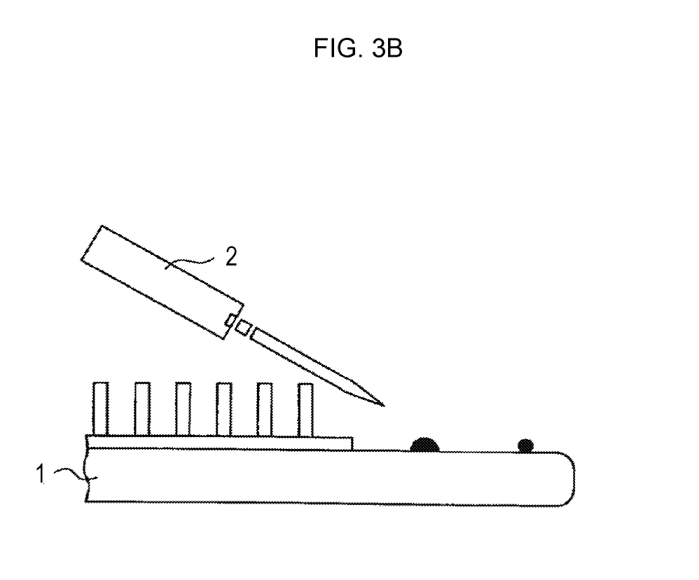

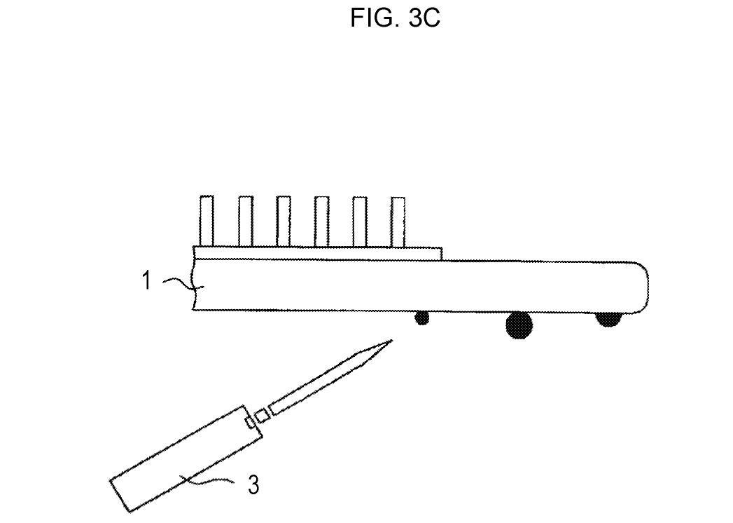

FIG. 3A schematically shows the thinner processing that is performed in the example. Thinner is jetted from above and below the semiconductor wafer 1 from nozzles 2 and 3 which are inclined with respect to a normal direction of the wafer so that the thinner is jetted in a radial direction towards the outer periphery. Foreign matter 4 derived from the photoresist (where the reflection preventing film, resist film, and top coat film are collectively called the photoresist) can be expected to have adhered to the circumferential portion of the wafer. The thinner cleans away such foreign matter effectively.

Generally, the thinner processing conditions are 500 rpm to 3000 rpm for the rotation speed for the spinner holding the semiconductor wafer, 30° to 60° for the angle between the nozzle direction and a normal direction to the wafer, 1 mm to 30 mm for the distance between the end of the nozzles and the wafer, 10 cc/min for the flow of the thinner, 0.1 mm to 1.5 mm for the nozzle diameters, 1000 rpm to 4000 rpm for speed of the spin drying, and 70° C. to 200° C. for the heat treatment.

FIG. 2B is an optical micrograph of the circumferential portion of the semiconductor wafer of the example after the cleaning using the thinner. As shown in FIG. 2B, a clean surface on which no particles are visible is obtained. When compared to the wafer before the thinner processing, which is shown in FIG. 2A, it is clear that the thinner processing has removed the foreign matter.

In step S16, if necessary, cleaning with pure water or pure water containing a surfactant may be performed. After the cleaning, the wafer is spin-dried.

In step S17, a process is performed in which the patterned resist film is used as a mask. For instance, gate electrode patterning may be performed. Thereafter, the semiconductor device is formed using well-known processes.

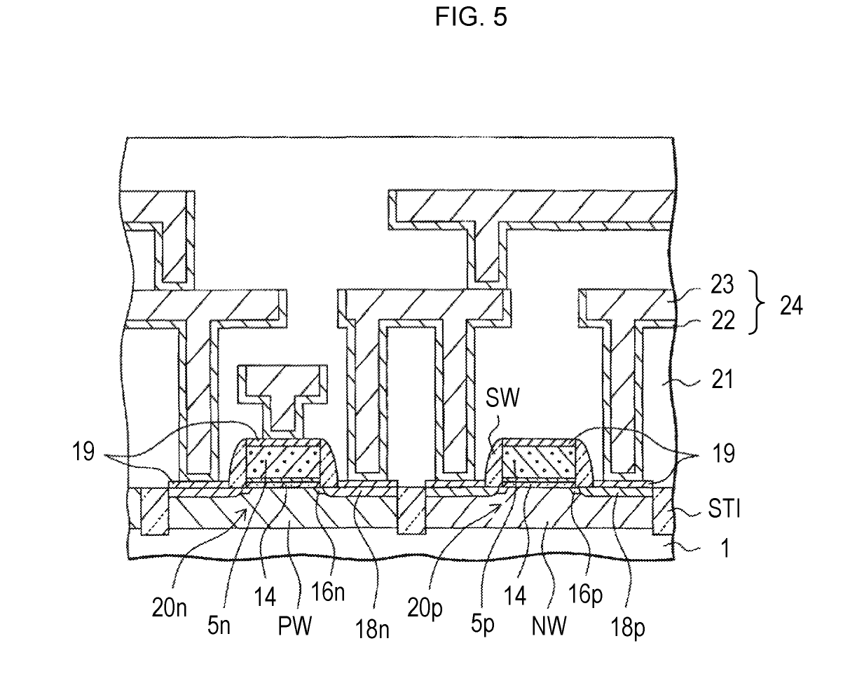

As shown in FIG. 5, an n-type polysilicon gate electrode 5n and an n-type extension region 16n are formed in a p-type well PW, and a p-type polysilicon gate electrode 5p and a p-type extension region 16p are formed in an n-type well NW. After forming a sidewall spacer SW on the gate electrode sidewall using a silicon oxide film or the like, an n-type source/drain region 18n is formed in the p-type well. With this process, an n-channel IG-FET 20n is formed. A p-type source/drain region 18p is formed in the n-type well NW. With this process, a p-channel IG-FET 20p is formed. Note that a silicide layer 19 is formed over the polysilicon gate electrode 5 and the source/drain region 18. The reference symbols “p” and “n” indicate different conduction types. The p-channel IG-FET 20p is configured in the same way as the n-channel IG-FET 20n except that the conduction types of the semiconductor regions have been reversed.

An inter-layer insulating film 21 is formed covering the gate electrode, and multi-layer wiring 24 is formed in the insulating film. The wiring 24 is constructed using a barrier metal layer 22 and a main wiring layer 23 of copper or the like.

Note that in the above-described embodiment, the thinner is simultaneously supplied from above and below the semiconductor wafer. The thinner processing, however, is not limited to this arrangement. Thinner cleaning may be performed from a nozzle above the wafer as shown in FIG. 3B and then from a nozzle below the wafer as shown in FIG. 3C. Moreover, this order may be reversed or limited to one of cleaning from below or cleaning from above as required. Furthermore, various changes can be made to the nozzles. For instance, changes may be made to the structure and number of the nozzles.

The above has described a semiconductor device manufacturing method according to the embodiment. However, the semiconductor device manufacturing method can be modified, exchanged, improved and combined in various ways without departing from the scope of the method of manufacturing the semiconductor device.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiment of the present invention has been described in detail, it should be understood that the various changes, substitutions, and alterations could be made hereto without departing from the spirit and scope of the invention.

What is claimed is:

1. A method for manufacturing a semiconductor device, comprising the steps of:
forming a resist film above a semiconductor wafer having a layer to be processed, the resist film not being formed on a circumferential portion of the semiconductor wafer;
exposing the resist film;
after exposing the resist film, forming a resist pattern by developing the resist film;
after forming the resist pattern by developing the resist film, cleaning the semiconductor wafer by supplying a thinner to the circumferential portion of the semiconductor wafer; and
after cleaning the semiconductor wafer, processing the layer to be processed of the semiconductor wafer using the resist pattern.

2. The method for manufacturing the semiconductor device according to claim 1, wherein
the step of forming the resist film above the semiconductor wafer includes the steps of:
supplying a resist film material onto the semiconductor wafer while rotating the semiconductor wafer; and
removing the resist film from the circumferential portion of the semiconductor wafer using a solvent.

3. The method for manufacturing the semiconductor device according to claim 2, wherein
the step of supplying the resist film material includes the steps of:
forming a reflection preventing film on the layer to be processed;
applying the resist film material to the reflection preventing film; and
after applying the resist film material, applying a top coat film, wherein
immersion lithography is used in the step of exposing the resist film, and
the top coat film is dissolved in the step of forming the resist pattern by developing the resist film.

4. The method for manufacturing the semiconductor device according to claim 3, wherein
the resist film is one of a group consisting of an acryl resin having an adamantyl group in a side chain, a COMA resin, an alicyclic acryl-COMA copolymer resin, and a cycloolefin resin, and
the top coat film is a fluorine-containing resin or a hydrocarbon resin.

5. The method for manufacturing the semiconductor device according to claim 1, wherein
the thinner is simultaneously jetted towards the circumferential portion of the semiconductor wafer from nozzles located above and below the circumferential portion of the semiconductor wafer.

6. The method for manufacturing the semiconductor device according to claim 1, wherein
the thinner is jetted towards the circumferential portion of the semiconductor wafer from a nozzle located either above and below the circumferential portion of the semiconductor wafer.

7. The method for manufacturing the semiconductor device according to claim 5, wherein
at least one of the nozzles are pointed in a radial direction of the semiconductor wafer and toward a peripheral side of the semiconductor wafer.

8. The method for manufacturing the semiconductor device according to claim 6, wherein
the nozzle is pointed in a radial direction of the semiconductor wafer and toward a peripheral side of the semiconductor wafer.

9. The method for manufacturing the semiconductor device according to claim 7, wherein
at least one of the nozzles is inclined at an angle of 30° to 60° with respect to a normal of the semiconductor wafer.

10. The method for manufacturing the semiconductor device according to claim 8, wherein
the nozzle is inclined at an angle of 30° to 60° with respect to a normal of the semiconductor wafer.

11. The method for manufacturing the semiconductor device according to claim 1, wherein
the thinner includes at least one of an ester, an ether, a lactone, and a ketone.

12. The method for manufacturing the semiconductor device according to claim 1, further comprising the step of:
forming an adhesion enhancing film on the layer to be processed before the step of forming the resist film above the semiconductor wafer.
